(19) United States
(12) Patent Application Publication
(10) Pub. No.: US 2008/0311485 A1
(43) Pub. Date: Dec. 18, 2008

(54) Photomasks Used to Fabricate Integrated Circuitry, Finished-Construction Binary Photomasks Used to Fabricate Integrated Circuitry, Methods of Forming Photomasks, and Methods of Photolithographically Patterning Substrates

(76) Inventors: William Stanton, Boise, ID (US); Fei Wang, Boise, ID (US)

Correspondence Address: WELLS ST. JOHN P.S., 601 W. FIRST AVENUE, SUITE 1300, SPOKANE, WA, 99201, US

(21) Appl. No.: 11/761,549

(22) Filed: Jun. 12, 2007

(51) Int. Cl. G03F 7/20; G03F 1/00

(52) U.S. Cl. 430/5; 430/322

(57) ABSTRACT

A finished-construction binary photomask used to fabricated integrated circuitry includes a substrate having a device region and a non-device region. The device region has a transparent substrate having a pair of spaced adjacent binary features formed thereover. The spaced adjacent binary features have an opaque material and a phase-shifting material. The phase-shifting material is received between the transparent substrate and the opaque material. Sidewalls of the spaced adjacent binary features may include a coating layer. Other embodiments, including methods, are contemplated.

### TECHNICAL FIELD

Embodiments disclosed herein pertain to photomasks used to fabricate integrated circuitry, to finished-construction binary photomasks used to fabricate integrated circuitry, to methods of forming photomasks, and to methods of photolithographically patterning substrates.

### BACKGROUND

Integrated circuitry fabrication may involve lithographic processing to transfer patterns formed in an imaging layer to underlying substrate material which will form part of the finished circuitry. For example, an imaging layer such as photoresist is provided over a layer to be patterned by etching. The imaging layer is then masked or otherwise processed such that selected regions of the imaging layer are exposed to suitable conditions which impact the solvent solubility of the exposed regions versus the unexposed regions. For example, the selected regions of the photoresist can be exposed to actinic energy through a mask pattern. The imaging layer is then solvent processed to remove one or the other of the processed or the non-processed regions, thereby forming the imaging layer to have mask openings extending partially or wholly therethrough to the underlying layer being patterned. In one type of processing, the substrate is then subjected to a suitable etching chemistry which is selected to etch the underlying layer or layers at least at a greater degree than the imaging layer, thereby transferring the imaging pattern to the underlying circuitry layer or layers. Alternate to etching, the substrate may be ion implanted or otherwise processed through the mask openings in the imaging layer.

Masks are usually fabricated to include a device region and a non-device region. In many applications, the non-device region is composed of a peripheral border region encircling the device region. The device region is the region in which the patterns represent the desired circuitry. The non-device region is the region in which patterns may be used for alignment structures, bar codes, and other purposes.

Various types of photolithographic masks are known in the art. For example, one type of mask includes a transparent plate covered with regions of a radiation blocking material, such as chromium, which is used to define the semiconductor feature pattern to be projected by the mask. Such masks are called binary masks, since radiation is completely blocked by the radiation blocking material and fully transmitted through the transparent plate in areas not covered by the radiation blocking material. Accordingly, such use binary features within the mask patterning area which include an opaque layer to essentially completely block the transmission of the actinic energy.

Due in part to limitations imposed by the wavelength of light or other actinic energy used to transfer the pattern, resolution can degrade at the edges of the patterns of binary photomasks. Such led to the development of phase-shifting photomasks which can increase the resolution of patterns by creating phase-shifting regions in transparent areas of the photomask. Standard phase-shift photomasks are generally formed in one of two manners. In a first, transparent films of appropriate thickness are deposited and patterned over the desired transparent areas using a second level lithography and etch technique. In a second, vertical trenches are etched into the transparent substrate. In both instances, the edges between the phase-shifted and unshifted regions generally result in a transition between high and low refractive index regions. These types of masks include transmission areas on either side of a patterned opaque feature. One of these transmission areas transmits light 180° out of phase from the other transmission areas, and both sides transmit approximately 100% of the incident radiation. Light diffracted underneath the opaque regions from the phase-shifted regions thus cancels each other, thereby creating more intense null or “dark area”.

Another type of phase-shifting mask is known as an “attenuated” or “half-tone” phase-shift mask. Such masks include both transparent and less transmissive regions. Actinic energy/radiation passing through a partially transmissive region of such a mask generally lacks the energy to substantially affect a resist layer exposed by the mask. Moreover, the partially transmissive regions of such masks are designed to shift passing radiation 180° relative to the radiation passing through the completely transmissive regions and, as a consequence, the radiation passing through the partially transmissive regions destructively interferes with radiation diffracting out from the edges of the completely transmissive regions. Masks have been proposed that use both binary features and attenuating face-shift mask features in the device area.

As minimum device pitch falls below 100 nanometers (i.e., where minimum feature size or minimum critical dimension falls below 50 nanometers), attenuated face-shift photomasks may begin to loose contrast with specific wave lengths of actinic energy.

### BRIEF DESCRIPTION OF THE DRAWINGS

FIG. 1 is a diagrammatic sectional view of a portion of a substrate in process in accordance with an embodiment of the invention.

FIG. 2 is a view of the FIG. 1 substrate at a processing subsequent to that shown by FIG. 1.

FIG. 3 is a diagrammatic sectional view of a portion of a substrate in accordance with an embodiment of the invention.

FIG. 4 is a diagrammatic sectional view of a portion of a substrate in accordance with an embodiment of the invention.

FIG. 5 is a diagrammatic sectional view of a portion of a substrate in accordance with an embodiment of the invention.

FIG. 6 is a diagrammatic sectional view of a portion of a substrate in accordance with an embodiment of the invention.

FIG. 7 is a diagrammatic sectional view of a portion of a substrate in process in accordance with an embodiment of the invention.

FIG. 8 is a view of the FIG. 7 substrate at a processing subsequent to that shown by FIG. 7, and using the substrate of FIG. 4.

### DETAILED DESCRIPTION OF EXAMPLE EMBODIMENTS

Some embodiments of the invention encompass photomasks used to fabricate integrated circuitry, including finished-construction binary photomasks used to fabricate integrated circuitry. In the context of this document, a “finished-construction” photomask is a mask which has been fabricated to completion whereby no additional layer(s)/material(s) will be deposited or removed relative to the substrate, with such being in a completed construction to be ready for use as a photomask in the fabrication of integrated circuitry. Accordingly, a “finished-construction” mask does not encompass any intermediate structure of a photomask that has not been fabricated to completion. However, some embodiments of the invention may also encompass intermediate construction photomasks, in other words those which are not of a finished-construction. Further, a “binary photomask” in the context of this document defines and requires the mask to have a device area where all the features employ essentially complete radiation blocking by opaque/radiation blocking material and adjacent essentially 100% transmissive/transparent regions. Further in the context of this document, a “binary feature” defines and requires the feature to function in an essential 100% complete radiation blocking manner. Certain embodiments of the invention do not require binary photomasks, and contemplate photomasks which may have a combination of binary features and non-binary features. However, all embodiments of the invention do contemplate utilizing at least some binary features in a photomask. Additionally, embodiments of the invention encompass methods of forming a photomask, and methods of photolithographically patterning a substrate.

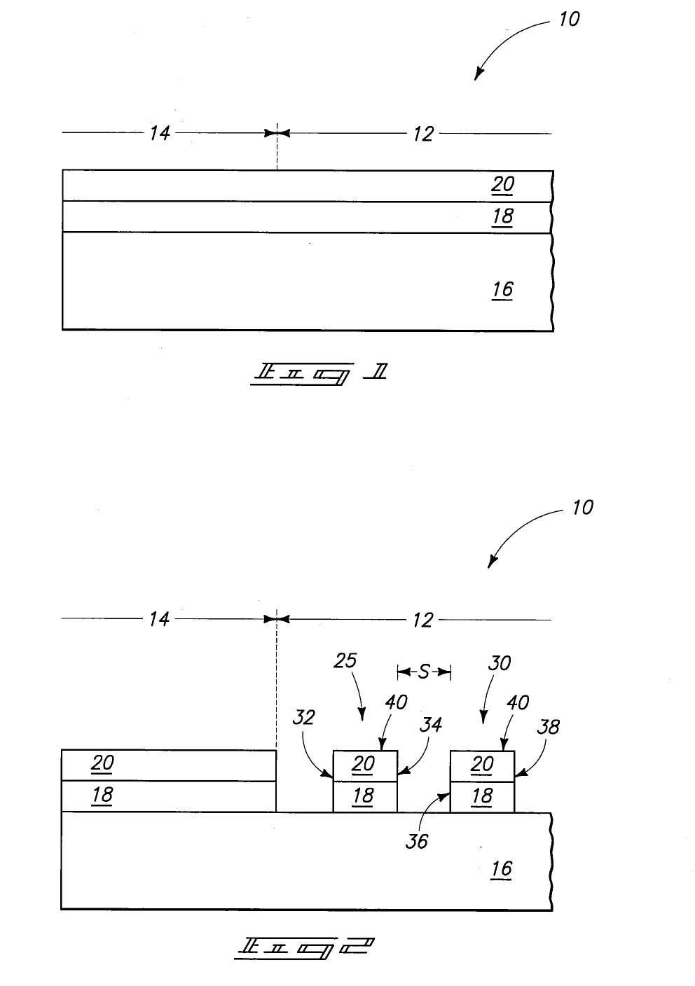

Referring initially to FIG. 1, a substrate is indicated generally with reference numeral 10. Such is depicted as comprising a device region 12 and a non-device region 14. Formation of mask pattern features may or may not occur with respect to both regions, with embodiments of the invention being material relative to fabrication with respect to device region 12.

Device region 12 of substrate 10 comprises a transparent substrate 16 comprising some suitable transparent material. Quartz is but one example, with an example thickness range being from 0.125 inch to 0.25 inch. A layer 18 of phase-shifting material has been formed over transparent material 16. Any existing or yet-to-be developed phase-shifting material is contemplated. In one embodiment, phase-shifting material 18 contains silicon, for example in one embodiment comprising a silicide. By way of example only, specific example embodiment phase-shifting materials include those selected from the group consisting of MoSiₓ, MoSiₓO_{y}, MoSiₓO_{y}N_{z}, TaₓHf_{y}, TaₓN_{y}, SiₓOₓN_{y}, and mixtures thereof, where “x”, “y”, and “z” are greater than zero. In one embodiment, an example thickness for phase-shifting material 18 is from about 400 Angstroms to about 2,000 Angstroms, with another example embodiment therewithin being from about 500 Angstroms to about 1,200 Angstroms in thickness. An opaque layer 20 is formed over phase-shifting material layer 18. Any existing or yet-to-be developed opaque material is contemplated. Chromium is but one example. An example thickness range is from about 500 Angstroms to about 1,000 Angstroms.

Referring to FIG. 2, portions of opaque layer 20 and phase-shifting material layer 18 have been etched to form a mask pattern of the opaque layer and the phase-shifting material over transparent material 16 at least within device region 12. In the depicted example embodiment, such etching has been completely through layers 20 and 18 to transparent substrate material 16, although such is not necessarily required. Regardless, device region 12 is depicted as comprising a pair of spaced adjacent binary features 25 and 30 formed over transparent substrate material 16. Patterning may also occur (not shown) within non-device region 14. The illustrated pair of spaced adjacent binary features 25, 30 comprises an opaque material 20 and a phase-shifting material 18, with phase-shifting material 18 being received between transparent substrate 16 and opaque material 20. Additional binary features would also of course be fabricated relative to device region 12, with only two such features being shown for clarity and simplicity.

For purposes of the continuing discussion, spaced adjacent binary features 25, 30 can be considered as comprising sidewalls 32, 34, 36, and 38, with sidewalls 34 and 36 comprising facing sidewalls of the respective spaced adjacent binary features. Further for purposes of the continuing discussion, opaque layer 20 of spaced adjacent binary features 25, 30 can be considered as comprising an outermost surface 40 which is orthogonal relative to sidewalls 32, 34 or 36, 38, respectively.

Regardless, FIG. 2 in but one example embodiment, can be considered as diagrammatically depicting a finished-construction binary photomask used to fabricate integrated circuitry, and independent of the method by which such may have been fabricated. In other words, in one example embodiment, FIG. 2 does not depict any intermediate construction but rather a final usable finished-construction binary photomask used to fabricate integrated circuitry. Regardless, in one example embodiment, facing sidewalls 34, 36 of spaced adjacent binary features 25, 30 which encompass opaque material 20 are spaced a distance “S” that is no greater than 50 nanometers apart, for example in conjunction with a problem which motivated the invention in overcoming contrast issues with attenuated phase-shift masks where minimum critical dimension between adjacent features fell to 50 nanometers and below for certain incident actinic energy wavelengths.

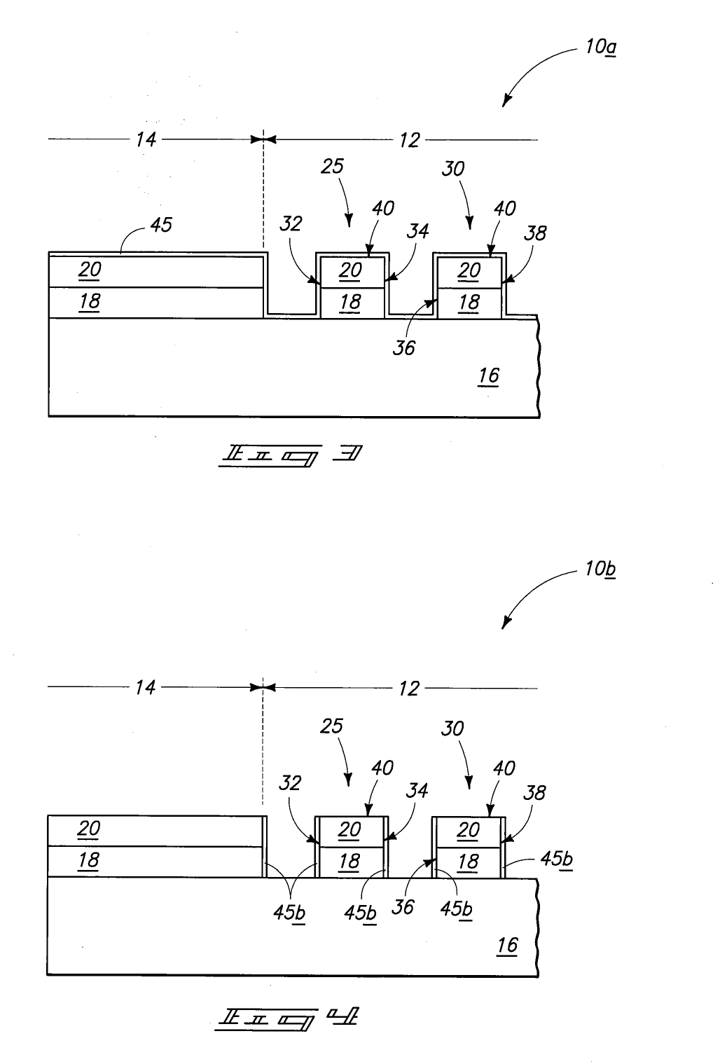

An additional or another embodiment photomask used to fabricate integrated circuitry is indicated in FIG. 3 with reference numeral 10a. Like numerals from the first-described embodiment are utilized where appropriate, with differences being indicated with different numerals or the suffix “a”. FIG. 3 depicts subsequent processing conducted relative to the substrate of FIG. 2. In FIG. 3, a coating layer 45 has been formed over sidewalls 32, 34, 36, and 38 of phase-shifting material 18 and opaque material 20 of spaced adjacent binary features 25 and 30. In one embodiment, an example thickness for coating layer 45 is from about 5 Angstroms to about 50 Angstroms. Other thicknesses might of course also be used. The coating layer may be any one or combination of dielectric, conductive, and semiconductive. In one particular embodiment, the coating layer is dielectric. By way of example only, example coating layer materials include SiO₂, Si₃N₄, SrF₂, MgF₂, MgF₂, Al₂O₃, BaF₂, Al, TiN, Cu, Cr, Si, and mixtures thereof. Layer 45 may be deposited by any suitable existing or yet-to-be developed manner including, by way of example only, chemical vapor deposition and atomic layer deposition. More than one layer might also of course be used.

FIG. 3 depicts but one example embodiment photomask used to fabricate integrated circuitry. Such may be a finished-construction photomask or an intermediate-construction photomask. Further and regardless, such may be a binary photomask or a combination photomask comprising both binary features (shown) and attenuated phase-shift masking features (not shown). Accordingly if a binary photomask, all features within device region 12 will be binary features wherein if a combination photomask, some of the features within device region 12 will be binary features and some will be attenuated phase-shift masking features.

Regardless, FIG. 3 also depicts one example embodiment wherein coating layer 45 is received over outermost orthogonal opaque material surface 40 of the respective spaced adjacent binary features 25, 30. Further, FIG. 3 depicts but one example embodiment wherein coating layer 45 is received over all of transparent substrate 16 between spaced adjacent binary features 25, 30.

Depending upon the nature and/or thickness of coating material 45, such may be essentially completely transmissive of certain actinic energy/radiation or effectively blocking thereof. Thickness of a material is conventionally considered or determined orthogonally relative to a closest surface over which the material is received. Accordingly and by way of example only, coating layer 45 is depicted as being of a uniform or constant thickness over materials 16, 18, and 20. However with respect to or in the context of passage of actinic energy through coating layer 45, such is of variable thickness particularly with respect to incident actinic energy which is orthogonal to substrate 10a. Such energy may go both through those vertically depicted “thicker” portions of layer 45 received immediately over sidewalls 32, 34, 36, and 38, and through those horizontally depicted “thinner” portions of layer 45 received between the “thicker” portions between spaced adjacent features 25 and 30. Accordingly, while coating material 45 composition and thickness may be effective to essentially allow patterning-effective actinic energy through the “thinner” portions of coating layer 45, the “thicker” portions may or may not allow passage of patterning-effective actinic energy therethrough. If not, the lateral thickness of coating layer 45 over sidewalls 32, 34, 36, and 38 effectively widens the feature widths, and of which the artisan can of course take into consideration when designing a mask.

An alternate example embodiment photomask 10b is depicted in FIG. 4. Like numerals from the first described embodiments are utilized where appropriate, with differences being indicated with the suffix “b”. In FIG. 4, coating layer 45b is not received over outermost orthogonal opaque material surface 40 of the respective spaced adjacent binary features 25, 30. Further, FIG. 4 depicts an example photomask embodiment wherein coating layer 45b is not received over all of transparent substrate material 16 received between the pair of spaced adjacent features 25, 30.

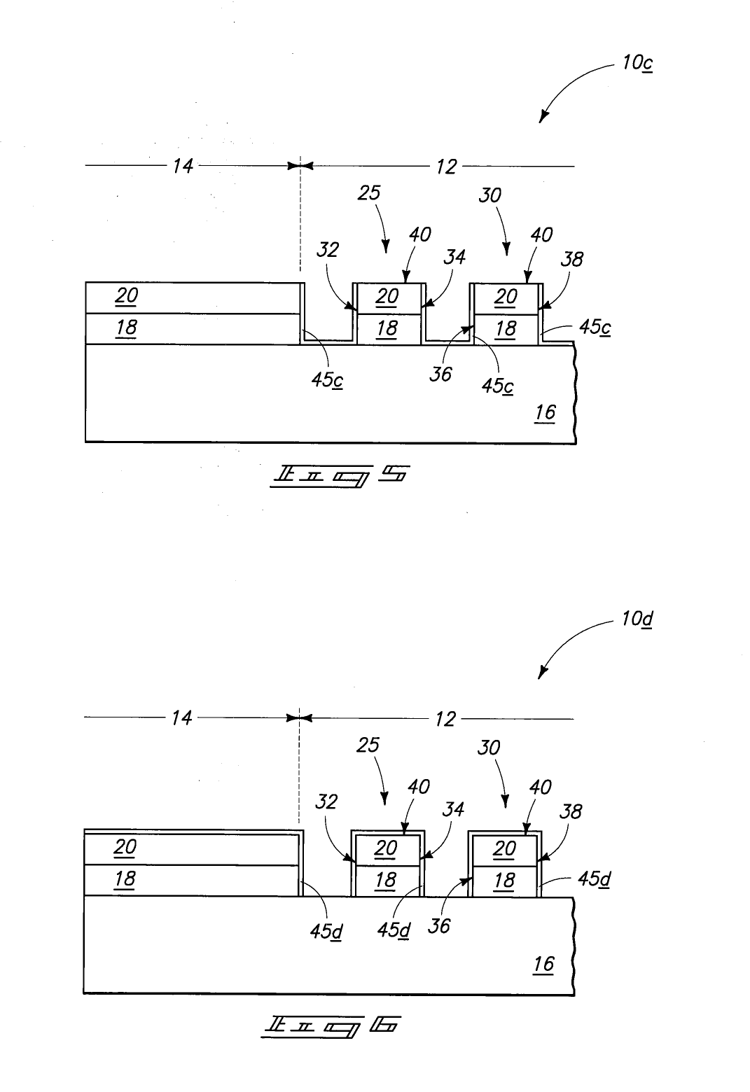

FIG. 5 illustrates another example embodiment photomask 10c. Like numerals from the above-described embodiments have been utilized where appropriate, with differences being indicated with the suffix “c”. Coating layer 45c in photomask 10c is not received over outermost orthogonal opaque material surface 40 of the respective spaced adjacent binary features 25, 30, but is received over all of substrate material 16 received between spaced adjacent binary features 25, 30.

FIG. 6 depicts still another example embodiment photomask 10d. Like numerals from the above-described embodiments have been utilized where appropriate, with differences being indicated with the suffix “d”. In the FIG. 6 embodiment, coating 45d is depicted as being received over outermost orthogonal opaque material surface 40 of the respective spaced adjacent binary features 25, 30, but not over all of substrate material 16 received between spaced adjacent binary features 25, 30.

One or more embodiments of the invention encompass methods of forming a photomask. Such include forming a layer of phase-shifting material over transparent material. An opaque layer is formed over the phase-shifting material layer. Portions of the opaque layer and the phase-shifting material layer are etched to form a mask pattern of the opaque layer and the phase-shifting material over the transparent material. The mask pattern comprises a pair of spaced adjacent binary features which comprise sidewalls. The sidewalls of the opaque layer and the phase-shifting material layer of the pair of spaced adjacent binary features are coated with a coating material. Fabrication of the above-described constructions, by way of example only, encompass possible such method implementations.

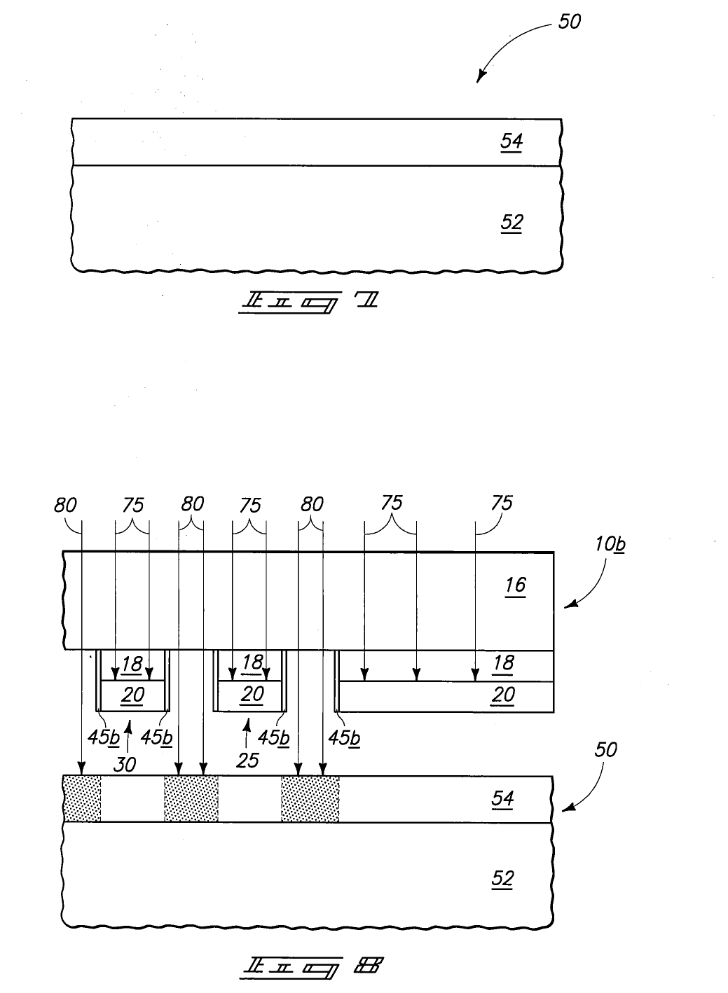

One or more embodiments of the invention also encompass methods of photolithographically patterning a substrate, for example using one or more of the above example photomasks. By way of example only, FIG. 7 depicts a substrate 50 to be photolithographically patterned. Such is depicted as comprising some substrate 52 having an imaging layer 54 formed thereover. In the context of this document, the term “imaging layer” defines a layer which is capable of having its solvent solubility changed by exposure to a suitable actinic energy, and whether existing or yet-to-be developed. Photoresist and certain polyimides are, by way of example only, such materials.

Referring to FIG. 8, a mask has been positioned proximate imaging layer 54. By way of example only, any of the above-described photomasks 10, 10a, 10b, 10c, or 10d are example usable photomasks, with photomask 10b being depicted in FIG. 8. Actinic energy is impinged at the mask through the transparent substrate and the phase-shifting material onto the opaque material (i.e., as depicted by arrows 75), as well as through the transparent material between the spaced adjacent binary features onto imaging layer 54 of substrate 50 (i.e., as depicted by arrows 80).

Without necessarily being limited by any theory of operation or necessarily in the end result in a broadest sense, the above-described photolithographic patterning with one or more of the example embodiment masks, at least when processing at critical dimensions at or below 50 nanometers, may provide better contrast in the layer being patterned. Such may occur by absorbing a greater quantity of a transverse magnetic component of the impinging actinic energy relative the facing sidewalls of spaced adjacent features than a transverse electric component of the impinging actinic energy. Alternately considered, a significant quantity of the transverse magnetic component is absorbed while a significant component of the transverse electric component of the impinging actinic energy is reflected. Such may be facilitated/enhanced by the presence of a coating layer received against the sidewalls of the spaced adjacent binary feature sidewalls as described above. Accordingly in such embodiments, the impinging may comprise absorbing a greater quantity of a transverse magnetic component of the impinging actinic energy by such coating layer than a transverse electric component of the impinging actinic energy. Three dimensional atomic simulations estimate that, with a FIG. 2 embodiment mask, an example quartz substrate 16 having a 68 nanometer thick MoSiₓ phase-shifting layer 18 and a 72 nanometer thick opaque chromium layer 20 and a spacing “S” of 40 nanometers can enhance line/space imaging contrast by more than 15% as compared to a binary mask not employing a phase shifting layer 18

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

We claim:

1. A finished-construction binary photomask used to fabricated integrated circuitry, comprising:
a substrate comprising a device region and a non-device region; and
the device region comprising a transparent substrate having a pair of spaced adjacent binary features formed thereover, the spaced adjacent binary features comprising an opaque material and a phase-shifting material, the phase-shifting material being received between the transparent substrate and the opaque material.

2. The photomask of claim 1 wherein the phase-shifting material is from about 400 Angstroms to about 2,000 Angstroms in thickness.

3. The photomask of claim 2 wherein the phase-shifting material is from about 500 Angstroms to about 1,200 Angstroms in thickness.

4. The photomask of claim 1 wherein the phase-shifting material contains silicon.

5. The photomask of claim 4 wherein the phase-shifting material comprises a silicide.

6. The photomask of claim 1 wherein the phase-shifting material comprises a material selected from the group consisting of MoSiₓ, MoSiₓO_{y}, MoSiₓO_{y}N_{z}, TaₓHf_{y}, TaₓN_{y}, SiₓOₓN_{y}, Al, TiN, Cu, Cr, Si, and mixtures thereof, where “x”, “y”, and “z” are greater than zero.

7. The photomask of claim 1 wherein the opaque material is from about 500 Angstroms to about 1,000 Angstroms in thickness.

8. The photomask of claim 1 wherein the opaque material of the spaced adjacent binary features comprises facing sidewalls that are spaced no greater than 50 nanometers apart.

9. The photomask of claim 1 wherein the spaced adjacent binary features comprise sidewalls, a coating layer being received over the sidewalls of the phase-shifting material and the opaque material of the spaced adjacent binary features.

10. The photomask of claim 9 wherein the coating layer is from about 5 Angstroms to about 50 Angstroms in thickness.

11. A photomask used to fabricated integrated circuitry, comprising:
a substrate comprising a device region and a non-device region;
the device region comprising a transparent substrate having a pair of spaced adjacent binary features formed thereover, the spaced adjacent binary features comprising an opaque material and a phase-shifting material, the phase-shifting material being received between the transparent substrate and the opaque material, the spaced adjacent binary features comprising sidewalls; and
a coating layer formed over the sidewalls of the phase-shifting material and the opaque material of the spaced adjacent binary features.

12. The photomask of claim 11 wherein all features within the device region are binary features.

13. The photomask of claim 11 wherein the coating layer is dielectric.

14. The photomask of claim 11 wherein the coating layer is semiconductive.

15. The photomask of claim 11 wherein the coating layer is conductive.

16. The photomask of claim 11 wherein the coating layer comprises a material selected from the group consisting of SiO₂, Si₃N₄, SrF₂, MgF₂, MgF₂, Al₂O₃, BaF₂, Al, TiN, Cu, Cr, Si, and mixtures thereof.

17. The photomask of claim 11 wherein the coating layer is from about 5 Angstroms to about 50 Angstroms in thickness.

18. The photomask of claim 11 wherein the opaque material of the spaced adjacent binary features comprises an outermost surface which is orthogonal the sidewalls, the coating layer being received over the outermost orthogonal opaque material surface.

19. The photomask of claim 11 wherein the opaque material of the spaced adjacent binary features comprises an outermost surface which is orthogonal the sidewalls, the coating layer not being received over the outermost orthogonal opaque material surface.

20. The photomask of claim 11 wherein the coating layer is received over the transparent substrate between the spaced adjacent binary features.

21. The photomask of claim 11 wherein,
the opaque material of the spaced adjacent binary features comprises an outermost surface which is orthogonal the sidewalls, the coating layer being received over the outermost orthogonal opaque material surface; and
the coating layer is received over the transparent substrate between the spaced adjacent binary features.

22. The photomask of claim 11 wherein the coating layer is not received over all of the transparent substrate received between the spaced adjacent binary features.

23. The photomask of claim 22 wherein the opaque material of the spaced adjacent binary features comprises an outermost surface which is orthogonal the sidewalls, the coating layer being received over the outermost orthogonal opaque material surface.

24. The photomask of claim 22 wherein the opaque material of the spaced adjacent binary features comprises an outermost surface which is orthogonal the sidewalls, the coating layer not being received over the outermost orthogonal opaque material surface.

25. The photomask of claim 11 wherein the opaque material of the spaced adjacent binary features comprises facing sidewalls that are spaced no greater than 50 nanometers apart.

26. A finished-construction binary photomask used to fabricated integrated circuitry, comprising:
a substrate comprising a device region and a non-device region;
the device region comprising a transparent substrate having a pair of spaced adjacent binary features formed thereover, the spaced adjacent binary features comprising an opaque material and a phase-shifting material, the phase-shifting material being received between the transparent substrate and the opaque material, the phase-shifting material being from about 400 Angstroms to about 2,000 Angstroms in thickness, the opaque material being from about 500 Angstroms to about 1,000 Angstroms in thickness, the spaced adjacent binary features comprising sidewalls, the sidewalls of the opaque material of the spaced adjacent binary features being spaced no greater than 50 nanometers apart; and
a coating layer from about 5 Angstroms to about 50 Angstroms thick formed over the sidewalls of the phase-shifting material and the opaque material of the spaced adjacent binary features.

27. A method of forming a photomask, comprising:
forming a layer of phase-shifting material over transparent material;
forming an opaque layer over the phase-shifting material layer;
etching portions of the opaque layer and the phase-shifting material layer to form a mask pattern of the opaque layer and the phase-shifting material over the transparent material, the mask pattern comprising a pair of spaced adjacent binary features comprising sidewalls; and
coating the sidewalls of the opaque layer and the phase-shifting material layer of the pair of spaced adjacent binary features with a coating material.

28. The method of claim 27 comprising coating the transparent material between the spaced adjacent binary features with the coating material.

29. The method of claim 27 wherein the opaque layer of the spaced adjacent binary features comprises an outermost surface which is orthogonal the sidewalls, and comprising coating the outermost orthogonal opaque layer surface with the coating material.

30. The method of claim 29 comprising coating the transparent material between the spaced adjacent binary features with the coating material.

31. The method of claim 27 wherein the coating comprises forming the coating material to have a thickness from about 5 Angstroms to about 50 Angstroms.

32. A method of photolithographically patterning a substrate, comprising:
forming an imaging layer over a substrate;
positioning a mask proximate the imaging layer, the mask comprising a transparent substrate having a pair of spaced adjacent binary features formed thereover, the spaced adjacent binary features comprising an opaque material and a phase-shifting material, the phase-shifting material being received between the transparent substrate and the opaque material; and
impinging actinic energy at the mask through the transparent substrate and the phase-shifting material onto the opaque material and through the transparent material between the spaced adjacent binary features onto the imaging layer on the substrate.

33. The method of claim 32 wherein the positioning is of a mask wherein the pair of spaced adjacent binary features comprise facing sidewalls, the impinging comprising absorbing a greater quantity of a transverse magnetic component of the impinging actinic energy relative the facing sidewalls than a transverse electric component of the impinging actinic energy.

34. The method of claim 32 wherein the positioning is of a mask wherein the spaced adjacent binary features comprise facing sidewalls of the opaque material and the phase-shifting material having a coating layer received over the facing sidewalls of the phase-shifting material and the opaque material of the spaced adjacent binary features.

35. The method of claim 34 wherein the impinging comprises absorbing a greater quantity of a transverse magnetic component of the impinging actinic energy by the coating layer than a transverse electric component of the impinging actinic energy.
